(19) United States
(12) Patent Application Publication
(10) Pub. No.: US 2012/0225219 A1
(43) Pub. Date: Sep. 6, 2012

(54) Apparatus And Process For Atomic Layer Deposition

(75) Inventor: Joseph Yudovsky, Campbell, CA (US)

(73) Assignee: Applied Materials, Inc., Santa Clara, CA (US)

(21) Appl. No.: 13/189,705

(22) Filed: Jul. 25, 2011

Related U.S. Application Data
(63) Continuation of application No. 13/037,890, filed on Mar. 1, 2011.

(51) Int. Cl. C23C 16/46; C23C 16/458; C23C 16/455

(52) U.S. Cl. 427/595; 118/724; 118/725; 427/424

(57) ABSTRACT

Provided are atomic layer deposition apparatus and methods including a gas distribution plate with a thermal element. The thermal element is capable of locally changing the temperature of a portion of the surface of the substrate by temporarily raising or lowering the temperature.

### STATEMENT OF RELATED CASES

This application is a continuation of U.S. patent application Ser. No. 13/037,890, filed Mar. 1, 2011, which is incorporated herein by reference.

### BACKGROUND

Embodiments of the invention generally relate to an apparatus and a method for depositing materials. More specifically, embodiments of the invention are directed to a atomic layer deposition chambers with linear reciprocal motion.

In the field of semiconductor processing, flat-panel display processing or other electronic device processing, vapor deposition processes have played an important role in depositing materials on substrates. As the geometries of electronic devices continue to shrink and the density of devices continues to increase, the size and aspect ratio of the features are becoming more aggressive, e.g., feature sizes of 0.07 μm and aspect ratios of 10 or greater. Accordingly, conformal deposition of materials to form these devices is becoming increasingly important.

During an atomic layer deposition (ALD) process, reactant gases are introduced into a process chamber containing a substrate. Generally, a region of a substrate is contacted with a first reactant which is adsorbed onto the substrate surface. The substrate is then contacted with a second reactant which reacts with the first reactant to form a deposited material. A purge gas may be introduced between the delivery of each reactant gas to ensure that the only reactions that occur are on the substrate surface.

There are many instances where the optimal reaction conditions for the first reactant are not the same as those of the second reactant. It is inefficient to change the temperature of the entire chamber and substrate between reactions. Additionally, some reaction conditions may cause long-term damage to the substrate and resulting device if conditions are maintained for too long. Therefore, there is an ongoing need in the art for improved apparatuses and methods of processing substrates by atomic layer deposition under more optimal reaction conditions.

### SUMMARY

Embodiments of the invention are directed to a deposition system comprising a processing chamber. A gas distribution plate is in the processing chamber. The gas distribution plate comprises a plurality of elongate gas ports configured to direct flows of gases toward a surface of a substrate. The gas distribution plate also comprises at least one thermal element adapted to cause a change in the temperature of a portion of the substrate. In specific embodiments, the thermal element is configured to cause a local change in the temperature at the surface of the substrate. Some specific embodiments further comprise a substrate carrier configured to move a substrate along an axis perpendicular to the plurality of elongate gas ports.

The thermal element of some embodiments is positioned within at least one elongate gas port. In some embodiments, the thermal element is positioned at a front face of the gas distribution plate between gas ports. In particular embodiments, the at least one thermal element is within an elongate gas port in flow communication with a purge gas. In detailed embodiments, the thermal element is positioned at one or more of the first end and the second end of the gas distribution plate.

In one more embodiments, the thermal element is a resistive heater. In detailed embodiments, the resistive heater is positioned at a front face of the gas distribution plate to directly heat the portion of the substrate. In specific embodiments, the resistive heater is positioned within at least one elongate gas port and is configured to heat the flow of gas in the elongate gas port.

In one or more embodiments, the thermal element is a radiative heater. In detailed embodiments, the radiative heater is a laser.

In some embodiments, the thermal element is a cooler. In detailed embodiments, the cooler is positioned within at least one elongate gas port and is configured to cool the gas flow in the elongate gas port.

Additional embodiments of the invention are directed to methods of processing a substrate. A substrate having a surface is moved laterally beneath a gas distribution plate. The gas distribution plate comprises a plurality of elongate gas ports including a fist gas port A to deliver a first gas and a second gas port B to deliver a second gas. The first gas is delivered to the substrate surface. The second gas is delivered to the substrate surface. The temperature of the substrate surface is locally changed.

In some embodiments, the substrate surface temperature is changed in a region extending from gas port A to gas port B. In detailed embodiments, the substrate surface temperature is changed at about gas port A. In specific embodiments, the substrate surface temperature is changed at about gas port B.

In detailed embodiments, the substrate surface temperature is changed by one or more of radiative heating, resistive heating and cooling the substrate. In specific embodiments, the substrate surface temperature is changed by one or more of resistively heating and cooling one or more of the first gas and the second gas.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic cross-sectional view of an atomic layer deposition chamber according to one or more embodiments of the invention;

FIG. 2 shows a susceptor in accordance with one or more embodiments of the invention;

FIG. 3 shows a partial cross-sectional side view of an atomic layer deposition chamber in accordance with one or more embodiments of the invention;

FIG. 4 shows a partial cross-sectional side view of an atomic layer deposition chamber in accordance with one or more embodiments of the invention;

FIG. 5 shows a partial cross-sectional side view of an atomic layer deposition chamber in accordance with one or more embodiments of the invention;

FIG. 6 shows a partial cross-sectional side view of an atomic layer deposition chamber in accordance with one or more embodiments of the invention;

FIG. 7 shows a partial cross-sectional side view of an atomic layer deposition chamber in accordance with one or more embodiments of the invention;

FIG. 8 shows a partial cross-sectional side view of an atomic layer deposition chamber in accordance with one or more embodiments of the invention; and

FIG. 9 shows a partial cross-sectional side view of an atomic layer deposition chamber in accordance with one or more embodiments of the invention.

### DETAILED DESCRIPTION

Embodiments of the invention are directed to atomic layer deposition apparatus and methods which provide improved processing of substrates. Specific embodiments of the invention are directed to atomic layer deposition apparatuses (also called cyclical deposition) incorporating at least one thermal element for changing the temperature of a portion of the substrate.

Some atomic layer deposition processes require different temperatures for different precursor reactions. If the temperature required for efficient reaction of precursor A is lower than for precursor B, a substrate needs to be locally heated while moving from precursor A to precursor B. A linear heater in the slot associated with precursor B, where a higher temperature is needed, can heat a substrate surface during or prior to deposition. This heater could be made of lamps or lasers array heating a substrate in the strip exposed to a precursor. The heater could be a resistive heater located in a proximity of a substrate surface and heating it prior to entering a deposition area, or could be heated by hot gases. Since the bulk substrate is cooler than a hot strip on the substrate, and only a top surface of the substrate gets hot, the temperature of the hot strip should decrease to a level required for efficient reaction of precursor A. Some additional cooling could be applied after slot B if necessary. Cooling can be done with, for example, a chilled plate or cold gases. Conversely, if the temperature required for efficient reaction of precursor B is lower than for precursor A, the substrate needs to be locally cooled while moving from A to B. A linear chiller or cold gases can lower a substrate temperature prior to slot B.

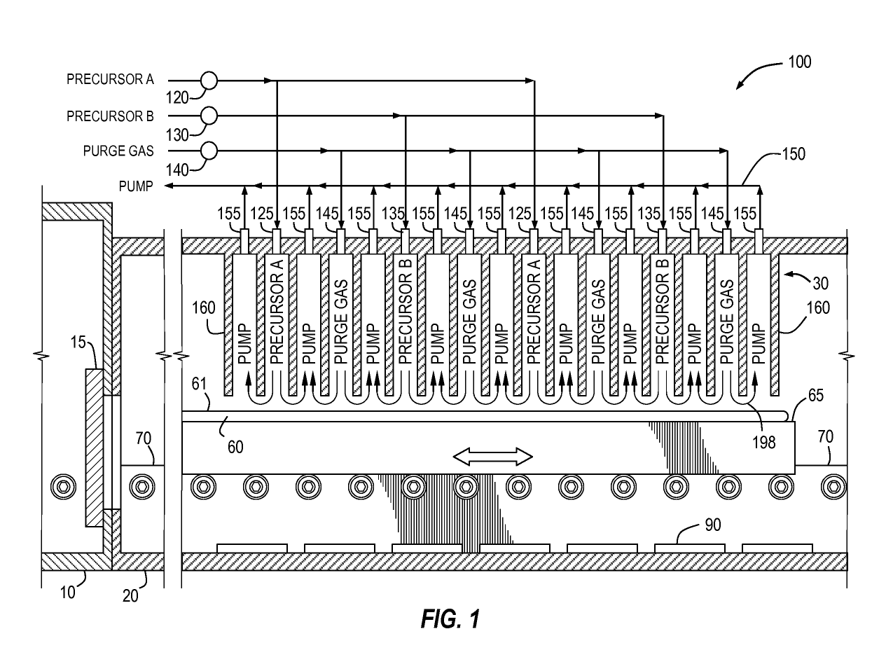

FIG. 1 is a schematic cross-sectional view of an atomic layer deposition system or system 100 in accordance with one or more embodiments of the invention. The system 100 includes a load lock chamber 10 and a processing chamber 20. The processing chamber 20 is generally a sealable enclosure, which is operated under vacuum, or at least low pressure. The processing chamber 20 is isolated from the load lock chamber 10 by an isolation valve 15. The isolation valve 15 seals the processing chamber 20 from the load lock chamber 10 in a closed position and allows a substrate 60 to be transferred from the load lock chamber 10 through the valve to the processing chamber 20 and vice versa in an open position.

The system 100 includes a gas distribution plate 30 capable of distributing one or more gases across a substrate 60. The gas distribution plate 30 can be any suitable distribution plate known to those skilled in the art, and specific gas distribution plates described should not be taken as limiting the scope of the invention. The output face of the gas distribution plate 30 faces the first surface 61 of the substrate 60.

Substrates for use with the embodiments of the invention can be any suitable substrate. In detailed embodiments, the substrate is a rigid, discrete, generally planar substrate. As used in this specification and the appended claims, the term “discrete” when referring to a substrate means that the substrate has a fixed dimension. The substrate of specific embodiments is a semiconductor substrate, such as a 200 mm or 300 mm diameter silicon substrate.

The gas distribution plate 30 comprises a plurality of gas ports configured to transmit one or more gas streams to the substrate 60 and a plurality of vacuum ports disposed between each gas port and configured to transmit the gas streams out of the processing chamber 20. In the detailed embodiment of FIG. 1, the gas distribution plate 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 is configured to inject a continuous (or pulse) stream of a reactive precursor of compound A into the processing chamber 20 through a plurality of gas ports 125. The precursor injector 130 is configured to inject a continuous (or pulse) stream of a reactive precursor of compound B into the processing chamber 20 through a plurality of gas ports 135. The purge gas injector 140 is configured to inject a continuous (or pulse) stream of a non-reactive or purge gas into the processing chamber 20 through a plurality of gas ports 145. The purge gas is configured to remove reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, thereby avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, it can be either capacitively or inductively coupled. The activation may also be generated by a thermally based technique, a gas breakdown technique, a high intensity light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas cushion plates may be employed.

In operation, a substrate 60 is delivered (e.g., by a robot) to the load lock chamber 10 and is placed on a shuttle 65. After the isolation valve 15 is opened, the shuttle 65 is moved along the track 70. Once the shuttle 65 enters in the processing chamber 20, the isolation valve 15 closes, sealing the processing chamber 20. The shuttle 65 is then moved through the processing chamber 20 for processing. In one embodiment, the shuttle 65 is moved in a linear path through the chamber.

As the substrate 60 moves through the processing chamber 20, the first surface 61 of substrate 60 is repeatedly exposed to the precursor of compound A coming from gas ports 125 and the precursor of compound B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the precursors or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discreet steps.

Sufficient space is generally provided at the end of the processing chamber 20 so as to ensure complete exposure by the last gas port in the processing chamber 20. Once the substrate 60 reaches the end of the processing chamber 20 (i.e., the first surface 61 has completely been exposed to every gas port in the processing chamber 20), the substrate 60 returns back in a direction toward the load lock chamber 10. As the substrate 60 moves back toward the load lock chamber 10, the substrate surface may be exposed again to the precursor of compound A, the purge gas, and the precursor of compound B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are configured so as not to remove adsorbed precursors from the substrate surface 110. The width between each partition, the number of gas ports disposed on the processing chamber 20, and the number of times the substrate is passed back and forth may also determine the extent to which the substrate surface 110 is exposed to the various gases. Consequently, the quantity and quality of a deposited film may be optimized by varying the above-referenced factors.

In another embodiment, the system 100 may include a precursor injector 120 and a precursor injector 130, without a purge gas injector 140. Consequently, as the substrate 60 moves through the processing chamber 20, the substrate surface 110 will be alternately exposed to the precursor of compound A and the precursor of compound B, without being exposed to purge gas in between.

The embodiment shown in FIG. 1 has the gas distribution plate 30 above the substrate. While the embodiments have been described and shown with respect to this upright orientation, it will be understood that the inverted orientation is also possible. In that situation, the first surface 61 of the substrate 60 will face downward, while the gas flows toward the substrate will be directed upward.

In yet another embodiment, the system 100 may be configured to process a plurality of substrates. In such an embodiment, the system 100 may include a second load lock chamber (disposed at an opposite end of the load lock chamber 10) and a plurality of substrates 60. The substrates 60 may be delivered to the load lock chamber 10 and retrieved from the second load lock chamber.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) between the load lock chamber 10 and the processing chamber 20. The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

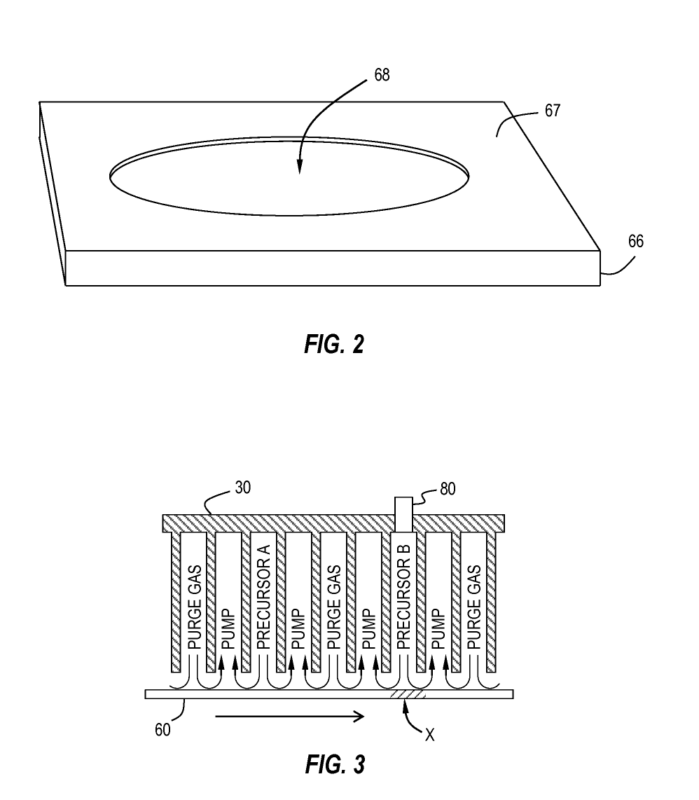

In still another embodiment, the top surface 67 of the susceptor 66 includes a recess 68 configured to accept the substrate 60, as shown in FIG. 2. The susceptor 66 is generally thicker than the thickness of the substrate so that there is susceptor material beneath the substrate. In detailed embodiments, the recess 68 is configured such that when the substrate 60 is disposed inside the recess 68, the first surface 61 of substrate 60 is level with the top surface 67 of the susceptor 66. Stated differently, the recess 68 of some embodiments is configured such that when a substrate 60 is disposed therein, the first surface 61 of the substrate 60 does not protrude above the top surface 67 of the susceptor 66.

In some embodiments, the substrate is thermally isolated from the carrier to minimize heat losses. This can be done by any suitable means, including but not limited to, minimizing the surface contact area and using low thermal conductance materials.

Substrates have an inherent thermal budget which is limited based on previous processing done on the substrate. Therefore, it is useful to limit the exposure of the substrate to large temperature variations to avoid exceeding this thermal budget, thereby damaging the previous processing. In some embodiments, the gas distribution plate 30 includes at least one thermal element 80 adapted to cause a local change in temperature at the surface of a portion of the substrate 60. The local change in temperature affects primarily a portion of the surface of the substrate 60 without affecting the bulk temperature of the substrate.

Referring to FIG. 3, in operation, the substrate 60 moves relative to the gas ports of the gas distribution plate 30, as shown by the arrow. The processing chamber 20, in this embodiment, is held at a temperature which is suitable for efficient reaction of precursor A with the substrate 60, or layer on the substrate 60, but is too low for efficient reaction of precursor B. Region X moves past gas ports with purge gases, vacuum ports and a first precursor A port, where the surface of the substrate 60 reacts with the first precursor A. Because the processing chamber 20 is held at a temperature suitable for the precursor A reaction, as the substrate 60 moves to precursor B, the region X is affected by the thermal element 80 and the local temperature of region X is increased. In detailed embodiment, the local temperature of region X is increased to a temperature which reaction of precursor B is favorable.

It will be understood by those skilled in the art that, as used and described herein, region X is an artificially fixed point or region of the substrate. In actual use, the region X would be, literally, a moving target, as the substrate is moving adjacent the gas distribution plate 30. For descriptive purposes, the region X shown is at a fixed point during processing of the substrate.

In detailed embodiments, the region X, which is also referred to as a portion of the substrate is limited in size. In some embodiments, the portion of the substrate effected by any individual thermal element is less than about 20% of the area of the substrate. In various embodiments, the portion of the substrate effected by any individual thermal element is less than about 15%, 10%, 5% or 2% of the area of the substrate.

The thermal element 80 can any suitable temperature altering device and can be positioned in many locations. Suitable examples of thermal elements 80 include, but are not limited to, radiative heaters (e.g., lamps and lasers), resistive heaters, liquid controlled heat exchangers and cooling plates.

FIGS. 3-6 show various thermal element 80 placements and types. It should be understood that these examples are merely illustrative of some embodiments of the invention are should not be taken as limiting the scope of the invention. In some embodiments, the thermal element 80 is positioned within at least one elongate gas port. Embodiments of this variety are shown in FIGS. 3-5. In FIG. 3, the thermal element 80 is a radiative heater positioned at an entrance to the gas port. The radiative heater can be used to directly heat region X of the substrate 60 as it passes adjacent to the gas port containing the radiative heater. Here, the region X of the substrate is heated and changed when the region X is adjacent about gas port B.

It will be understood by those skilled in the art that there can be more than one thermal element 80 in any given gas distribution plate 30. An example of this would be a gas distribution plate 30 with two repeating units of precursor A and precursor B. If the reaction temperature of precursor B is higher than precursor A, a thermal element may be placed within, or around/near each of the precursor B gas ports.

In specific embodiments, the radiative heater is a laser which is directed along the gas port toward the surface of the substrate 60. It can be seen from FIG. 3 that as region X passes the thermal element, the elevated temperature remains for a period of time. The amount of time that the temperature remains elevated for that region depends on a number of factors. Accordingly, in some embodiments, the radiative heater is positioned at one of the vacuum port or purge gas ports before precursor B gas port. In these embodiments, region X maintains the residual heat long enough to enhance reaction of precursor B. In these embodiments, the region X is heated and the temperature changed in a region extending from about gas port A to about gas port B.

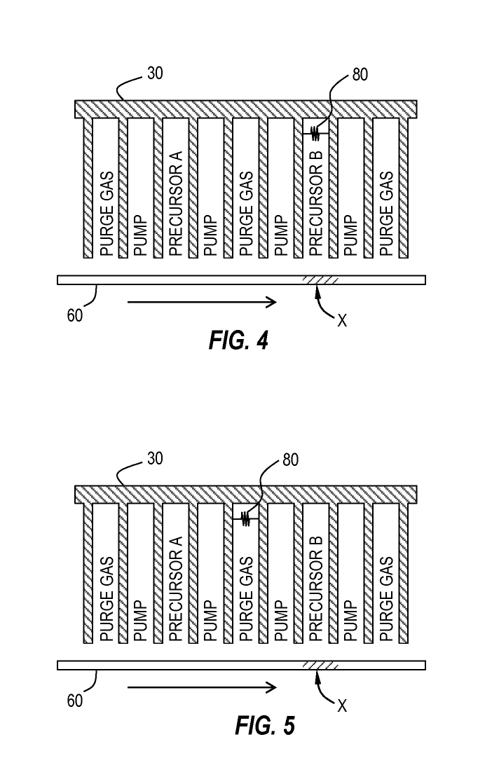

FIGS. 4 and 5 show alternate embodiments of the invention in which the thermal element 80 is a resistive heater. The resistive heater can be any suitable heater known to those skilled in the art including, but not limited to, tubular heaters. In FIG. 4, the resistive heater is positioned within a gas port so that the gas passing the resistive heater is heated. In specific embodiments, the gas passing the resistive heater is heated to a temperature sufficient to provide efficient reaction with the substrate or layer on the substrate. The heated gas passing the resistive heater can then heat the region X of the substrate. In this and similar embodiments, the region X of the substrate 60 surface temperature is changed when the region X at adjacent about gas port B.

FIG. 5 shows an alternate embodiment in which the resistive heater is placed within a purge gas port. The placement of this resistive hater is after the region X encounters precursor A and before it encounters precursor B. The resistive heater of this embodiments heats the purge gas, which upon contact with the substrate, heats the portion, region X, of the substrate. In detailed embodiments, thermal element 80 is positioned such that the purge gas is heated or cooled prior to being flowed through the gas distribution plate.

Some embodiments similar to those of FIGS. 4 and 5 replace the resistive heater with a cooling plate. The cooling plate can be placed within the gas flow in the gas ports to cool the temperature of the gas exiting these ports. In some embodiments, the gas being cooled is one or more of precursor A or precursor B. In detailed embodiments, the thermal element 80 is a cooling plate placed in a purge gas port to cool the purge gas to cool the temperature of the surface of the substrate.

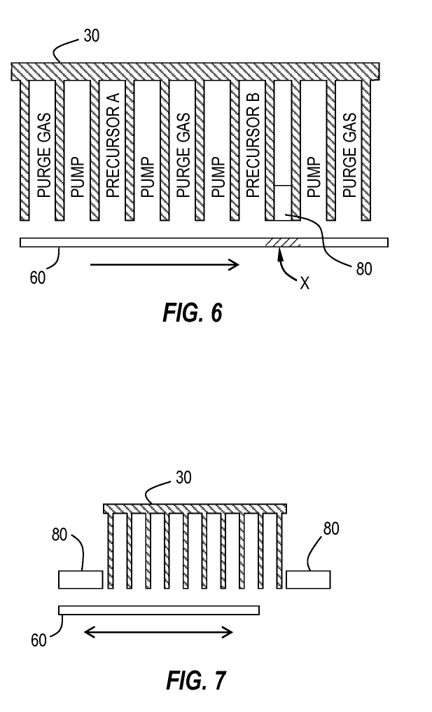

FIG. 6 shows another embodiment of the invention in which the thermal element 80 is positioned at a front face of the gas distribution plate 30. The thermal element 80 is shown in a portion of the gas distribution plate which is between two gas ports. The size of this thermal element can be adjusted as necessary to minimize the gap between the adjacent gas ports. In specific embodiments, the thermal element has a size that is about equal to the width of the partitions 160. The thermal element 80 of these embodiments can be any suitable thermal element including radiative and resistive heaters, or coolers. This particular configuration may be suitable for resistive heaters and cooling plates because of the proximity to the surface of the substrate 60. In detailed embodiments, the thermal element 80 is a resistive heater positioned at a front face of the gas distribution plate to directly heat the portion, region X, of the substrate 60. In specific embodiments, thermal element 80 is a cooling plate positioned at a front face of the gas distribution plate to directly cool the portion, region X, of the substrate 60. In detailed embodiments, the thermal element 80 is positioned on either side of a gas port. These embodiments are particularly suitable for use with reciprocal motion processing where the substrate move back and forth adjacent the gas distribution plate 30.

The thermal element 80 may be positioned before and/or after the gas distribution plate 30. This embodiment is suitable for both reciprocal processing chambers in which the substrates moves back and forth adjacent the gas distribution plate, and in continuous (carousel or conveyer) architectures. In detailed embodiments the thermal element 80 is a heat lamp. In the specific embodiment shown in FIG. 7, there are two thermal elements 80, one on either side of the gas distribution plate, so that in reciprocal type processing, the substrate 60 is heated in both processing directions.

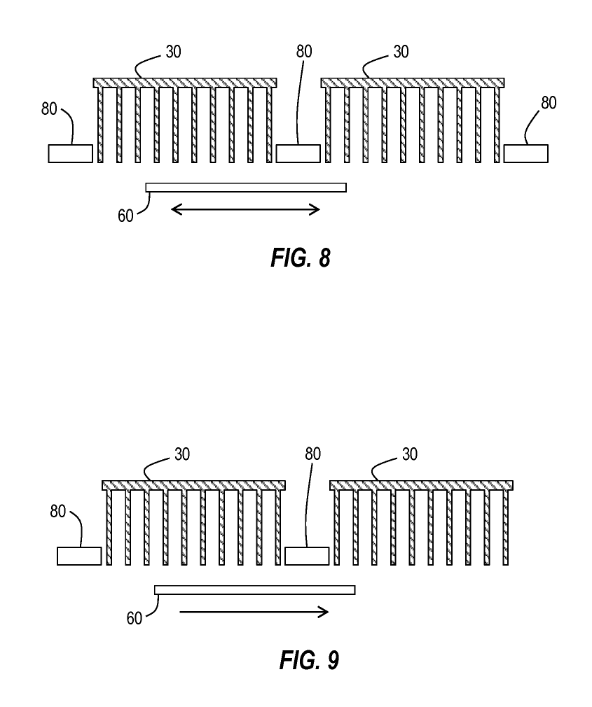

FIG. 8 shows another embodiment of the invention in which there are two gas distribution plates 30 with thermal elements 80 before, after and between each of the gas distribution plates 30. This embodiment is of particular use with reciprocal processing chambers as it allows for more layers to be deposited in a single cycle (one pass back and forth). Because there is a thermal element 80 at the beginning and end of the gas distribution plates 30, the substrate 60 is affected by the thermal element 80 before passing the gas distribution plate 30 in either the forward (e.g., left-to-right) or reverse (e.g., right-to-left) movement. It will be understood by those skilled in the art that the processing chamber 20 can have any number of gas distribution plates 30 with thermal elements 80 before and/or after each of the gas distribution plates 30 and the invention should not be limited to the embodiments shown.

FIG. 9 shows another embodiment similar to that of FIG. 8 without the thermal element 80 after the last gas distribution plate 30. Embodiments of this sort are of particular use with continuous processing, rather than reciprocal processing. For example, the processing chamber 20 may contain any number of gas distribution plates 30 with a thermal element 80 before each plate.

In some embodiments, the thermal element 80 is a gas distribution plate, or portion of a gas distribution plate, which is configured to direct a stream of gas, which has been heated or cooled, toward the surface of the substrate. Additionally, the gas distribution plate can be heated or cooled so that proximity to the substrate can cause a change in the substrate surface temperature. For example, in a continuous processing environment, the processing chamber may have several gas distribution plates, or a single plate with a large number of gas ports. One or more of the gas distribution plates (where there are more than one) or some of the gas ports can be configured to provide heated or cooled gas or radiant energy.

Additional embodiments of the invention are directed to methods of processing a substrate. A substrate 60 is moved laterally adjacent a gas distribution plate 30 comprising a plurality of elongate gas ports. The elongate gas ports include a first gas port A to deliver a first gas and a second gas port B to deliver a second gas. The first gas is delivered to the substrate surface and the second gas is delivered to the substrate surface. The local temperature of the substrate surface is changed during processing. In some embodiments, the temperature is changed locally after delivering the first gas to the substrate surface and before delivering the second gas to the substrate surface. In detailed embodiments, the temperature is changed locally about the same time as delivering the first gas or about the same time as delivering the second gas.

In detailed embodiments, the substrate surface temperature is directly changed by one or more of radiative heating, resistive heating and cooling the substrate surface. In specific embodiments, the substrate surface temperature is indirectly changed by one or more of resistively heating and cooling one or more of the first gas and the second gas.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

1. A deposition system to process a substrate having a surface, comprising:
a processing chamber; and
a gas distribution plate in the processing chamber, the gas distribution plate having a plurality of elongate gas ports that direct flows of gases toward the surface of the substrate;
the gas distribution plate including a first thermal element located at a first end of the gas distribution plate;
the gas distribution plate including a second thermal element located at a second end of the gas distribution plate.

2. The deposition system of claim 1, comprising a reciprocating substrate carrier that carries the substrate in a first direction past the plurality of elongate gas ports and then in a second direction past the plurality of elongate gas ports.

3. The deposition system of claim 1, wherein the first and second thermal elements are resistive heaters.

4. The deposition system of claim 1, wherein the first and second thermal elements are radiative heaters.

5. The deposition system of claim 4, wherein the radiative heaters are lasers.

6. The deposition system of claim 1, wherein the thermal elements are coolers.

7. A deposition system to process a substrate having a surface, comprising:
a processing chamber; and
a gas distribution plate in the processing chamber, the gas distribution plate having a plurality of elongate gas ports that direct flows of gases toward the surface of the substrate;
the gas distribution plate including a heating element adapted to raise temperature on at least a portion of the surface of the substrate; and
the gas distribution plate including a cooling element adapted to lower temperature on at least a portion of the surface of the substrate.

8. The deposition system of claim 7, wherein the heating element is positioned within at least one elongate gas port.

9. The deposition system of claim 7, wherein the heating element is positioned at a front face of the gas distribution plate between gas ports.

10. The deposition system of claim 7, wherein the heating element is a resistive heater.

11. The deposition system of claim 7, wherein the heating element is a radiative heater.

12. The deposition system of claim 12, wherein the radiative heater is a laser.

13. The deposition system of claim 7, wherein the cooling element is located in a purge gas port in the gas distribution plate.

14. The deposition system of claim 7, wherein the cooling element is positioned within at least one elongate gas port and cools the gas flow in the elongate gas port.

15. The deposition system of claim 7, further comprising a substrate carrier that moves the substrate along an axis perpendicular to the plurality of elongate gas ports.

16. A method of processing a substrate comprising:
laterally moving the substrate having a surface beneath a gas distribution plate comprising a plurality of elongate gas ports including a first gas port A to deliver a first gas and a second gas port B to deliver a second gas;
delivering the first gas from the gas port A to the substrate surface after locally changing temperature of the substrate surface with a first thermal element;
delivering the second gas from the gas port B to the substrate surface after locally changing temperature of the substrate surface with a second thermal element; and
locally changing temperature of the substrate surface.

17. The method of claim 16, wherein substrate surface temperature is changed in a region extending from gas port A to gas port B.

18. The method of claim 16, wherein the substrate surface temperature is changed by one or more of radiative heating, resistive heating and cooling the substrate.

19. The method of claim 16, wherein the substrate surface temperature is changed by one or more of resistively heating and cooling one or more of the first gas and the second gas.

20. The method of claim 16, comprising reciprocally moving the substrate under gas port A and gas port B.
